(19) United States
(12) Patent Application Publication
(10) Pub. No.: US 2024/0015930 A1
(43) Pub. Date: Jan. 11, 2024

(54) IMMERSION COOLING SYSTEM

(71) Applicant: Wiwynn Corporation, New Taipei City (TW)

(72) Inventors: Tai-Ying TU, New Taipei City (TW); Zi-Ping WU, New Taipei City (TW); Chun-Wei LIN, New Taipei City (TW); Ting-Yu PAI, New Taipei City (TW)

(21) Appl. No.: 18/344,098

(22) Filed: Jun. 29, 2023

(30) Foreign Application Priority Data
Jul. 8, 2022 (TW) 111125829

(51) Int. Cl. H05K 7/20

(52) U.S. Cl. CPC H05K 7/20327; H05K 7/203; H05K 7/20318; H05K 7/20818

(57) ABSTRACT

An immersion cooling system including a cooling tank, an immersion unit, a plurality of piezoelectric units, and a piezoelectric driver is provided. The cooling tank has a receiving portion. The immersion unit is in the receiving portion and the immersion unit includes a boiler plate. One or more channels are between the piezoelectric units, and the at least one channel is in communication with the boiler plate. The piezoelectric driver is for driving each of the piezoelectric units to generate a deformation.

### CROSS-REFERENCE TO RELATED APPLICATION

This non-provisional application claims priority under 35 U.S.C. § 119(a) to Patent Application No. 111125829 filed in Taiwan, R.O.C. on Jul. 8, 2022, and the entire contents of which are hereby incorporated by reference.

### BACKGROUND

### Technical Field

The instant disclosure relates to an immersion cooling system, particularly an immersion cooling system having piezoelectric units.

### Related Art

An immersion cooling system usually refers to a system capable of transferring the heat generated by an electronic device to a heat transfer fluid by submerging the electronic device in a heat transfer fluid; therefore, the temperature of the electronic device can be reduced. Hence, the working temperature of the electronic device can be maintained within a proper range to reach desired working performance and service life of the electronic device.

In the process of transferring the heats from the electronic device to the heat transfer fluid, the heat transfer fluid with a lower boiling point will be first boiled and vaporized, and thus bubbles in a large amount will be quickly generated at interfaces (as well as the proximity of the interfaces) between the electronic device and the heat transfer fluid. These bubbles will be widely dispersed in the heat transfer fluid.

### SUMMARY

In view of this, according to some embodiments, an immersion cooling system is provided and comprises a cooling tank, an immersion unit, a plurality of piezoelectric units, and a piezoelectric driver. The cooling tank has a receiving portion. The immersion unit is in the receiving portion and the immersion unit comprises a boiler plate. At least one channel is between the piezoelectric units, and the at least one channel is in communication with the boiler plate. The piezoelectric driver is for driving each of the piezoelectric units to generate a deformation.

According to some embodiments, the deformation of each of the piezoelectric units has a deformation direction, and the deformation directions of each two adjacent of the piezoelectric units are in opposite directions.

According to some embodiments, the piezoelectric units have a plurality of the channels gradually expanding or tapered along a direction away from the boiler plate. According to some other embodiments, the piezoelectric units have a plurality of the channels gradually expanding upwards along a vertical direction.

According to some embodiments, the piezoelectric units respectively have vertical heights substantially equal to each other, and the vertical heights of the piezoelectric units are not lower than a vertical height of the boiler plate.

According to some embodiments, each of the piezoelectric units comprises a piezoelectric frame and an acting section. The action section is at a location of the piezoelectric frame, and the location is adjacent to the boiler plate.

According to some embodiments, the immersion cooling system further comprises a heat transfer fluid. The heat transfer fluid is received in the receiving portion and at least submerges the boiler plate of each of the immersion units. Each of the immersion unit further comprises a main body frame and an electronic device in the main body frame. The electronic device comprises a heating element contacting the boiler plate.

According to some embodiments, the boiler plate faces a surface of the heat transfer fluid. According to some other embodiments, the boiler plate has a main surface substantially parallel to a vertical line.

According to some embodiments, the immersion cooling system further comprises a plurality of the cooling tanks, a plurality of the immersion units, and a plurality of the piezoelectric drivers. Each of the cooling tanks corresponds to a corresponding one of the immersion units, and each of the immersion units corresponds to corresponding piezoelectric units and a corresponding one of the piezoelectric drivers.

To sum up, according to some embodiments, an immersion cooling system having piezoelectric units is provided. Each of the piezoelectric units is adjacent to a boiler plate. At least one channel may be formed between the piezoelectric units. In some embodiments, when the boiler plate in operation is submerged in the heat transfer fluid, a large number of bubbles generated in the heat transfer fluid will pass through the channels. The flow of the bubbles would be changed (and even accelerated) by deformations of the channels. Hence, in some embodiments, through the piezoelectric units, the bubbles can be prevented from staying in place or flowing to other locations in the heat transfer fluid. Furthermore, according to some embodiments, through improving conditions of the bubbles (such as staying in place or flowing to other locations), pollutants generated at the surface of the boiler plate (or the proximity of the boiler plate) can be also removed at the same time, so that the pollutants that would further affect the cooling performance of the boiler plate can be prevented from being accumulated at the surface of the boiler plate (or the proximity of the boiler plate).

### BRIEF DESCRIPTION OF THE DRAWINGS

FIG. 1A illustrates a schematic structural view of an immersion cooling system according to some embodiments;

FIG. 1B illustrates a partial schematic perspective view of an immersion cooling system applied to a cabinet-mounted server system according to some embodiments;

FIG. 2 illustrates a schematic perspective and working view according to a partial section A shown in FIG. 1A;

FIG. 3 illustrates a schematic working view in a first view (i.e., the XZ plane) of a single immersion unit of the immersion cooling system shown in FIG. 2;

FIG. 4 illustrates a schematic working view in a second view (i.e., the YZ plane) of a single immersion unit of the immersion cooling system shown in FIG. 2;

FIG. 5A illustrates a schematic view in a third view (i.e., the XY plane) according to a first embodiment of a partial section B shown in FIG. 4;

FIG. 5B illustrates a schematic view in the third view (i.e., the XY plane) according to a second embodiment of the partial section B shown in FIG. 4;

FIG. 5C illustrates a schematic view in the third view (i.e., the XY plane) according to a third embodiment of the partial section B shown in FIG. 4;

FIG. 5D illustrates a schematic view in the third view (i.e., the XY plane) according to a fourth embodiment of the partial section B shown in FIG. 4;

FIG. 5E illustrates a schematic view in the third view (i.e., the XY plane) according to a fifth embodiment of the partial section B shown in FIG. 4;

FIG. 6A illustrates a schematic view in the second view (i.e., the YZ plane) according to a first embodiment of the partial section B shown in FIG. 4;

FIG. 6B illustrates a schematic view in the second view (i.e., the YZ plane) according to a second embodiment of the partial section B shown in FIG. 4;

FIG. 6C illustrates a schematic view in the second view (i.e., the YZ plane) according to a third embodiment of the partial section B shown in FIG. 4;

FIG. 6D illustrates a schematic view in the second view (i.e., the YZ plane) according to a fourth embodiment of the partial section B shown in FIG. 4;

FIG. 6E illustrates a schematic view in the second view (i.e., the YZ plane) according to a fifth embodiment of the partial section B shown in FIG. 4;

FIG. 7A illustrates a schematic view in the second view (i.e., the YZ plane) according to a sixth embodiment of the partial section B shown in FIG. 4;

FIG. 7B illustrates a schematic view in the second view (i.e., the YZ plane) according to a seventh embodiment of the partial section B shown in FIG. 4;

FIG. 7C illustrates a schematic view in the second view (i.e., the YZ plane) according to an eighth embodiment of the partial section B shown in FIG. 4;

FIG. 7D illustrates a schematic view in the second view (i.e., the YZ plane) according to a ninth embodiment of the partial section B shown in FIG. 4;

FIG. 8A illustrates a schematic view in the first view (i.e., the XZ plane) according to a first embodiment of the partial section B shown in FIG. 4;

FIG. 8B illustrates a schematic view in the first view (i.e., the XZ plane) according to a second embodiment of the partial section B shown in FIG. 4;

FIG. 8C illustrates a schematic working view in the first view (i.e., the XZ plane) according to a third embodiment of the partial section B shown in FIG. 4;

FIG. 8D illustrates a schematic working view in the first view (i.e., the XZ plane) according to a fourth embodiment of the partial section B shown in FIG. 4;

FIG. 8E illustrates a schematic working view in the first view (i.e., the XZ plane) according to a fifth embodiment of the partial section B shown in FIG. 4;

FIG. 8F illustrates a schematic working view in the first view (i.e., the XZ plane) according to a sixth embodiment of the partial section B shown in FIG. 4;

FIG. 8G illustrates a schematic working view in the first view (i.e., the XZ plane) according to a seventh embodiment of the partial section B shown in FIG. 4;

FIG. 9 illustrates a schematic working view in the second view (i.e., the YZ plane) of a partial section A of a single immersion unit of the immersion cooling system according to some embodiments;

FIG. 10 illustrates a schematic working view in the second view (i.e., the YZ plane) of a partial section A of a single immersion unit of the immersion cooling system according to some embodiments;

FIG. 11 illustrates a schematic working view of a plurality of immersion units of the immersion cooling system according to some embodiments;

FIG. 12 illustrates a schematic working view of a plurality of immersion units of the immersion cooling system according to some embodiments;

FIG. 13A illustrates a schematic working view in the first view (i.e., the XZ plane) of a single immersion unit of the immersion cooling system according to some embodiments;

FIG. 13B illustrates a schematic working view in the first view (i.e., the XZ plane) of a single immersion unit of the immersion cooling system according to some embodiments;

FIG. 14A illustrates a schematic working view in the first view (i.e., the XZ plane) of a single immersion unit of the immersion cooling system according to some embodiments; and

FIG. 14B illustrates a schematic working view in the first view (i.e., the XZ plane) of a single immersion unit of the immersion cooling system according to some embodiments.

### DETAILED DESCRIPTION

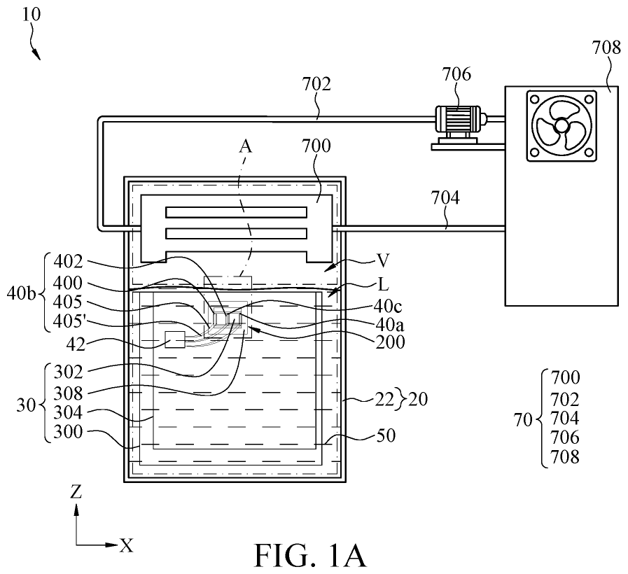

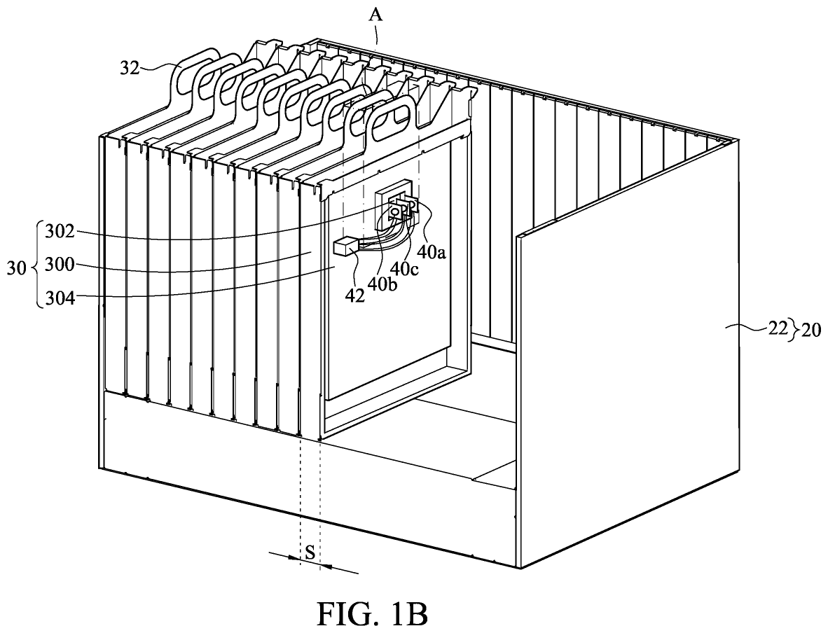

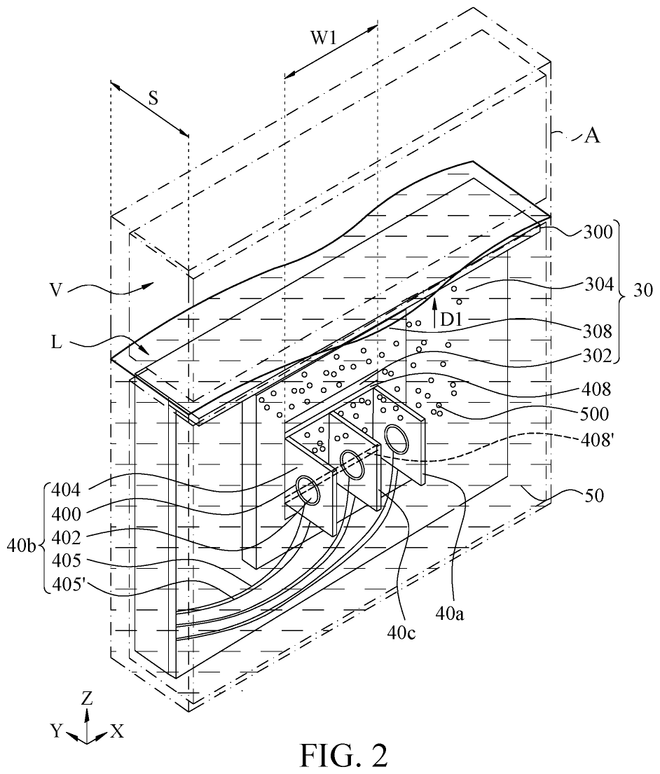

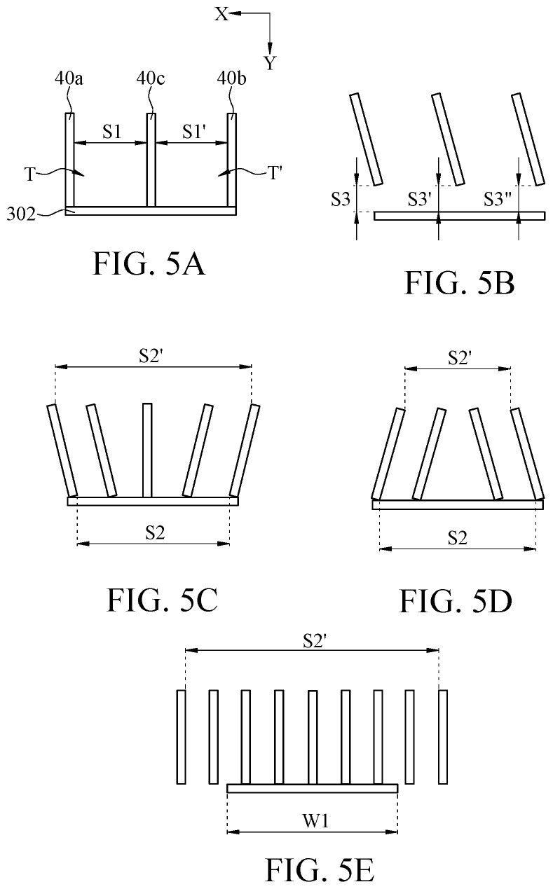

Please refer to FIG. 1A and FIG. 2 at the same time. FIG. 1A illustrates a schematic structural view of an immersion cooling system 10 according to some embodiments, and FIG. 2 illustrates a schematic perspective and working view according to a partial section A shown in FIG. 1A. An immersion cooling system 10 is provided and comprises a cooling tank 20, an immersion unit 30, a plurality of piezoelectric units 40a, 40b, 40c, and a piezoelectric driver 42. The cooling tank 20 has a receiving portion 200. The immersion unit 30 is in the receiving portion 200 and comprises a boiler plate 302. The piezoelectric units 40a, 40b, 40c are elements comprising the dielectric materials which can be applied with an electric potential difference to further generate a mechanical deformation. For example, the piezoelectric units 40a, 40b, 40c may independently be a piezoelectric diaphragm. The dielectric materials may be, but not limited to, polar polymers that can be polarized, such as plastics, rubbers, ceramics, or combinations comprising any two or more thereof. Specifically, the dielectric materials may be, but not limited to, barium titanate (BTO), lead titanate, lead zirconate titanate (PZT), or polyvinylidene fluoride (PVDF). In the partial section A shown in FIG. 2, through dividing a side of the partial section A that is adjacent to the boiler plate 302, a channel T (as shown in FIG. 5A and will be described later) would be formed between the two piezoelectric units 40a, 40c; meanwhile, a channel T′ (as shown in FIG. 5A and will be described later) would be formed between the two piezoelectric units 40b, 40c. Each of the channels T, T′ is in communication with the boiler plate 302. That is, in this embodiment, one of two sides of each of the channels T, T′ is at the boiler plate 302. The piezoelectric driver 42 is connected to the piezoelectric units 40a, 40b, 40c so as to drive the piezoelectric units 40a, 40c to respectively generate deformations due to piezoelectric effects. Hence, in some embodiments, through the piezoelectric units 40a, 40b, 40c, the channels T, T′ that are flexible may be deformed, so that the channels T, T′ can respectively serve as guiding channels with functions of driving and disturbing (which will be described later).

Please refer to FIG. 1B. FIG. 1B illustrates a partial schematic perspective view of an immersion cooling system 10 applied to a cabinet-mounted server system according to some embodiments. Only a partial structure for receiving the lower part of a cabinet 22 of the immersion unit 30 shown in FIG. 1A is shown in FIG. 1B (it is noted that, for ease of understanding, a front plate at the lower part of the cabinet 22 is removed from the figure). The immersion cooling system 10 may be equipped with a single immersion unit 30 or a plurality of immersion units 30. The single immersion unit 30 may be, but not limited to, a rack-mounted server unit. In some embodiments, the immersion cooling system 10 may be also equipped with a plurality of the immersion units 30, and the immersion cooling system 10 may be, but not limited to, a cabinet-mounted server system shown in FIG. 1B. The cabinet-mounted server system comprises a cabinet 22, the cabinet 22 receives a plurality of immersion units 30, and each of the immersion units 30 is a rack-mounted server unit with a thickness S. The thickness S of each of the rack-mounted server units may be identical or different from each other; for example, the thickness S may be 48.26 cm (i.e., 19 inch). The thickness S (as shown in FIG. 1B) of each of the rack-mounted server units may be adjusted according to different specifications of the server. For example, the thickness S may be a multiple of 4.445 cm; that is, the thickness S may be, but not limited to, 1U (i.e., 4.445 cm), 2U (i.e., 2*4.445 cm; 8.89 cm), 3U (i.e., 3*4.445 cm; 13.335 cm), or 4U (i.e., 4*4.445 cm; 17.78 cm). Therefore, the immersion units 30 or the cooling tank 20 where the immersion units 30 are received can serve as a system-level device (such as a server) with various thickness S, or a system-assembly-level device (such as a server assembly).

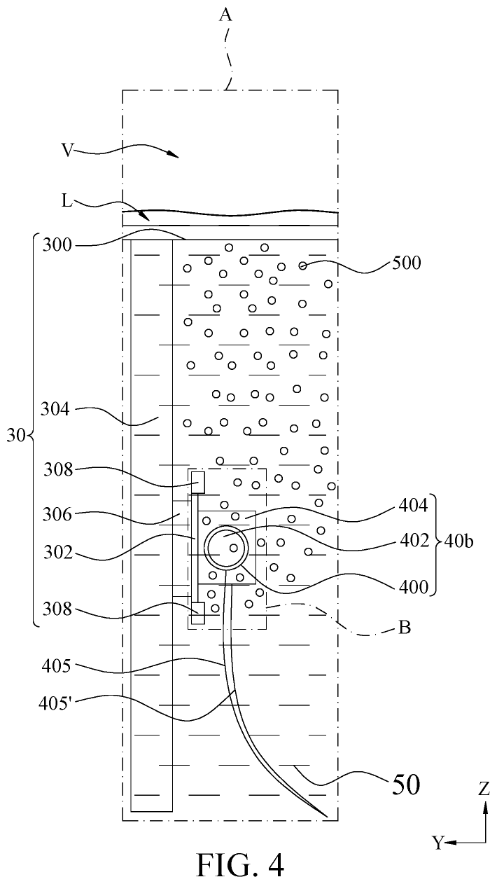

The immersion units 30 serving as rack-mounted server units according to some embodiments are described below as an exemplified illustration. Each of the immersion units comprises a main body frame 300 and an electronic device 304. The main body frame 300 is for fixing the electronic device 304. The electronic device 304 may be, but not limited to, devices such as a printed circuit board (i.e., PCB), a motherboard, a server, or the like. The dimension of the main body frame 300 may be, for example, complied with the dimensions of 1U, 2U, 3U, or 4U. The electronic device 304 comprises a heating element 306 (which is shown in FIG. 4 and will be described later), and the boiler plate 302 contacts the heating element 306. The heating element 306 may be, but not limited to, a chip, and the chip may be, but not limited to, a CPU or a display chip (i.e., a graphics processing unit, GPU). When the electronic device 304 is in operation, the heats generated by the heating element 306 would be conducted to the boiler plate 302. In some embodiments, as shown in FIG. 1B, each of the immersion units 30 further comprises a body handle 32. The body handle 32 is on one side of the main body frame 300, and the side is away from the lower portion of the main body frame 300. Hence, in some embodiments, through the body handle 32, the rack-mounted immersion units 30 can be taken out from, for example, the cabinet 22 or the cooling tank 20. Alternatively, in some embodiments, the immersion unit 30 can be received in, for example, the cabinet 22 or the cooling tank 20 conveniently. To illustrate each of the embodiments more clearly, in the instant disclosure, the body handle 32 is omitted and not shown in black line in the figures other than FIG. 1B.

Please refer to FIG. 2. In operation, the heat transfer fluid 50 may be received in the receiving portion 200 and at least submerge the boiler plate 302. Hence, the receiving portion 200 has a gas-phase space V and a liquid-phase space L. That is, in this embodiment, the liquid-phase space L is a space where the heat transfer fluid 50 is received in the receiving portion 200. When the boiler plate 302 physically contacts the heat transfer fluid 50, the heats of the boiler plate 302 can be conducted to the heat transfer fluid 50. The heat transfer fluid is a non-conductive fluid with a boiling point being less than or equal to a working temperature of the boiler plate 302. Therefore, the critical boiling point of the heat transfer fluid 50 would be quickly reached by absorbing the heats to further vaporize the heat transfer fluid 50, so that a large number of bubbles 500 would be generated. Next, through the channel T formed by the piezoelectric units 40a, 40c (which will be described later), the bubbles 500 would move to the surface of the heat transfer fluid 50 due to buoyancy or compression by the channel T. Therefore, the bubbles 500 would move from the proximity of the boiler plate 302, generally along a first direction D1 (e.g., the +Z direction shown in FIG. 2), to further escape to the gas-phase space V. Hence, in some embodiments, the bubbles 500 in a large amount can be prevented from being attached to or accumulated at the proximity of the boiler plate 302 of the immersion cooling system 10. Therefore, in some embodiments, the overall cooling performance of the immersion cooling system 10 can also be prevented from being affected by the reduced contact possibilities between the boiler plate 302 and the liquid-phase heat transfer fluid 50.

In some embodiments, the boiler plate 302 has a main surface. The main surface is a surface contacting the heat transfer fluid 50 and substantially parallel to a vertical line (e.g., the Z direction or the first direction D1 as shown in FIG. 2). Hence, the boiler plate 302 can be extendingly configured along a direction (for example, the Z direction as shown in FIG. 2) that is substantially perpendicular to the surface of the heat transfer fluid 50. Alternatively, in some embodiments, the boiler plate 302 can be extendingly configured along a plane (e.g., the XZ plane as shown in FIG. 2) that is substantially perpendicular to the surface of the heat transfer fluid 50. Therefore, the inner space of the immersion unit 30 can be utilized more sufficiently. Furthermore, in some embodiments, in the limited inner space of the immersion unit 30, more of the immersion units 30 can be meanwhile configured along a direction (e.g., the Z direction as shown in FIG. 2) that is substantially perpendicular to the surface of the heat transfer fluid 50. Alternatively, more of the immersion units 30 can be meanwhile configured along a plane (e.g., the XZ plane as shown in FIG. 2) that is substantially perpendicular to the surface of the heat transfer fluid 50. Hence, a plenty of the immersion units 30 and the boiler plates 302 corresponding thereto can be cooled synchronously and more efficiently.

In some embodiments, the immersion cooling system 10 further comprises a condensation device 70 (as shown in FIG. 1A). The condensation device 70 comprises a condenser 700, a condensation pump 706, and a heat exchanger 708. The condenser 700 is above the surface of the heat transfer fluid 50. Referring to FIG. 1A, the condenser 700 is in the gas-phase space V of the receiving portion 200. Through a first condensation pipe 702 and a second condensation pipe 704, the condensation pump 706 allows a heat exchange fluid to be circulated between the heat exchanger 708 and the condenser 700. The heat exchange fluid may be, but not limited to, water. When the immersion cooling system 10 is in operation, the gas-phase heat transfer fluid 50 escaping to the gas-phase space V would contact the surface of the condenser 700. Since the surface temperature of the condenser 700 is lower than the temperature of the heat transfer fluid 50, the heats would be transferred from the gas-phase heat transfer fluid 50 to the condenser 700. The gas-phase heat transfer fluid 50 would be then condensed into the liquid-phase heat transfer fluid 50 after the temperature of the gas-phase heat transfer fluid 50 is reduced. The liquid-phase heat transfer fluid 50 would then drop back to the heat transfer fluid 50 received in the liquid-phase space L. After the condenser 700 absorbs the heats of the gas-phase heat transfer fluid 50, the heats would be further guided to the heat exchanger 708 by the heat exchange fluid. Then, after the temperature of the heat exchange fluid is reduced, the heat exchange fluid would be guided back to the condenser 700.

Please refer to FIG. 2 and FIG. 4 at the same time. FIG. 4 illustrates a schematic working view in a second view (i.e., the YZ plane) of a single immersion unit 30 of the immersion cooling system 10 shown in FIG. 2. In FIG. 4, the electronic device 304 is fixed to the main body frame 300, and the heating element 306 of the electronic device 304 contacts the boiler plate 302. In some embodiments, the immersion unit 30 further comprises a bracket 308 fixed to the boiler plate 302, and the boiler plate 302 is maintained by the bracket 308 to normally contact the heating element 306. The bracket 308 may be fixed to the electronic device 304, the main body frame 300, or a combination of the electronic device 304 and the main body frame 300. In some embodiments, the material of the bracket 308 may be, but not limited to, Bakelite, metal, plastic, or combinations comprising any two or more thereof.

Please refer to FIG. 2. In some embodiments, the immersion cooling system 10 comprises a plurality of piezoelectric units 40a, 40b, 40c and a plurality of piezoelectric fixing elements 408, 408′. Two ends of each of the piezoelectric fixing elements 408, 408′ are across two sides of the boiler plate 302. For example, two ends of each of the piezoelectric fixing elements 408, 408′ are connected to the bracket 308 at the two sides of the boiler plate 302. Each of the piezoelectric units 40a, 40b, 40c is connected to the piezoelectric fixing elements 408, 408′. A channel T (or a channel T′) that is in communication with the boiler plate 302 is formed between the two adjacent piezoelectric units 40a, 40c (or the two adjacent piezoelectric units 40b, 40c), which is shown in FIG. 5A and will be described later. In some embodiments, the materials of the piezoelectric fixing elements 408, 408′ may be, but not limited to, Bakelite, metal, plastic, or combinations comprising any two or more thereof. Therefore, in operation, through the piezoelectric units 40a, 40b, 40c respectively connected to the piezoelectric fixing elements 408, 408′, the channels T, T′ can be maintained at locations just as the original locations before the operation. Hence, the cooling performance of the boiler plate 302 can be prevented from being apparently affected. In some embodiments, the piezoelectric units 40a, 40c are fixed to the piezoelectric fixing elements 408, 408′ by in a manner of latching or bolting.

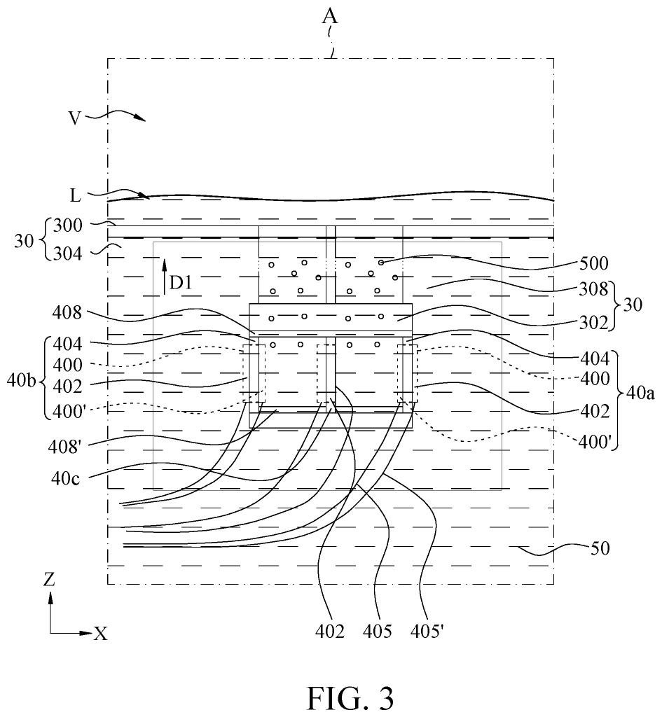

Please refer to FIG. 2 and FIG. 3 at the same time. FIG. 3 illustrates a schematic working view in a first view (i.e., the XZ plane) of a single immersion unit 30 of the immersion cooling system 10 shown in FIG. 2. In some embodiments, each of the piezoelectric units 40a, 40c is electrically connected to the piezoelectric driver 42 (as shown in FIG. 1A) by a pair of piezoelectric wires 405, 405′. Therefore, through each of the piezoelectric units 40a, 40b, driven by the piezoelectric driver 42, deformations of each of the piezoelectric units 40a, 40c would be correspondingly generated. That is, deformations of the channel T (or the channel T′) between the piezoelectric units 40a, 40c (or the piezoelectric units 40c, 40b) would be correspondingly generated.

In some embodiments shown in FIG. 2 and FIG. 3, one or more of the piezoelectric units (e.g., the piezoelectric units 40a, 40c) may independently comprise a piezoelectric frame 404 and two acting sections 400, 400′ in pair. Each of the piezoelectric frames 404 is adjacent to the boiler plate 302 so that the piezoelectric units 40a, 40c can be adjacent to the boiler plate 302. For example, each of the piezoelectric frames 404 may be configured on the piezoelectric fixing elements 408, 408′. Each of the piezoelectric frames 404 comprises a dielectric layer 402. The acting sections 400, 400′ in pair are respectively at two opposite sides of the dielectric layer 402 of the piezoelectric frame 404. Hence, the acting section 400, the dielectric layer 402, and the acting section 400′ together form a double layered piezoelectric unit (i.e., a bimorph) with a sandwich structure. Each of two piezoelectric wires 405, 405′ in pair is connected to a corresponding one of the acting sections 400, 400′ which are respectively at the two opposite sides of the dielectric layer 402. Through the driving of the piezoelectric driver 42 and the piezoelectric wires 405, 405′, an electric potential difference between the acting sections 400, 400′ would be generated, so that molecules in the dielectric layer 402 would be polarized and thus a deformation of the dielectric layer 402 would be generated. In some embodiments, the materials of the acting sections 400, 400′ may independently be, but not limited to, metal or alloy, such as copper or silver. In some embodiments, the material of the dielectric layer 402 may be, but not limited to, plastic, rubber, ceramic, or combinations comprising any two or more thereof; for example, barium titanate (BTO), lead titanate, lead zirconate titanate (PZT), or polyvinylidene fluoride (PVDF). In some embodiments, each of the acting sections 400, 400′ is a circular acting section having an outer diameter, and the outer diameter of each of the acting sections 400, 400′ may be, but not limited to, any value ranging between 20 mm and 30 mm. In some embodiments, each of the acting sections 400, 400′ is a circular acting section or a non-circular action section having a curvature radius, and the curvature radius of each of the acting sections 400, 400′ may be, but not limited to, any value ranging between 10 mm and 15 mm.

In some embodiments shown in FIG. 2 and FIG. 3, one or more of the piezoelectric units (e.g., the piezoelectric unit 40b) may independently comprise a piezoelectric frame 404 and an acting section 400. Each of the piezoelectric frames 404 is adjacent to the boiler plate 302 so that the piezoelectric unit 40b can be adjacent to the boiler plate 302. For example, each of the piezoelectric frames 404 may be configured on the piezoelectric fixing elements 408, 408′. Each of the piezoelectric frames 404 comprises a dielectric layer 402. The acting section 400 is at one side of the dielectric layer 402 of the piezoelectric frame 404. Hence, the acting section 400 and the dielectric layer 402 together form a single layered piezoelectric unit (i.e., a unimorph). Each of two piezoelectric wires 405, 405′ in pair is connected to a corresponding one of the acting sections 400, 400′ which are respectively at the two opposite sides of the dielectric layer 402. Through the driving of the piezoelectric driver 42 and the piezoelectric wires 405, 405′, an electric potential difference between the acting section 400 and the dielectric layer 402 would be generated, so that molecules in the dielectric layer 402 would be polarized and thus a deformation of the dielectric layer 402 would be further generated. In some embodiments, the material of the acting section 400 may be, but not limited to, metal or alloy, such as copper or silver. In some embodiments, the material of the dielectric layer 402 may be, but not limited to, plastic, rubber, ceramic, or combinations comprising any two or more thereof; for example, barium titanate (BTO), lead titanate, lead zirconate titanate (PZT), or polyvinylidene fluoride (PVDF).

In some embodiments, each of the piezoelectric units 40a, 40b, 40c may be independently a single layered piezoelectric unit or a double layered piezoelectric unit, so that the immersion cooling system 10 in various combinations of the piezoelectric units 40a, 40b, can be provided. Hence, through the various combinations of the piezoelectric units 40a, 40c and the correspondingly different electric potential differences, the flow of the bubbles 500 can be controlled more efficiently. Therefore, the bubbles 500 attached to or accumulated at the proximity of the boiler plate 302 can be further removed.

Please refer to FIG. 4 and FIG. 5A. FIG. 5A illustrates a schematic view in a third view (i.e., the XY plane) according to a first embodiment of a partial section B shown in FIG. 4 (to illustrate each of the embodiments more clearly, in the instant disclosure, the piezoelectric units 40a, 40b, 40c, the boiler plate 302, the channels T, T′, and the numerals of the piezoelectric units 40a, 40b, 40c, the boiler plate 302, the channels T, T′ are only shown in FIG. 5A). In some embodiments, a plurality of channels T, T′ (as shown in FIG. 5A) are between the piezoelectric units 40a, 40b, 40c. In FIG. 5A, a channel T with a channel width S1 is between the two adjacent piezoelectric units 40a, 40c, a channel T′ with a channel width S1′ is between the two adjacent piezoelectric units 40c, 40b, and the channel widths S1, S1′ may be substantially equal to or not equal to each other. Furthermore, in some embodiments, the piezoelectric units 40a, 40b, 40c are parallel to each other along a direction that is away from the boiler plate 302 (e.g., the Y direction as shown in FIG. 5A). Therefore, the bubbles 500 would leave from the boiler plate 302 along the channels T, T′.

Please refer to FIG. 4 and FIG. 5B at the same time. FIG. 5B illustrates a schematic view in the third view (i.e., the XY plane) according to a second embodiment of the partial section B shown in FIG. 4 (to illustrate each of the embodiments more clearly, in the instant disclosure, the numerals of the piezoelectric units 40a, 40b, 40c, the boiler plate 302, and the channels T, T′ are omitted and not further illustrated in FIG. 5B). In some embodiments shown in FIG. 5B, all of the piezoelectric units 40a, 40b, 40c are configured to be inclined along the same direction (e.g., the left side as shown in FIG. 5B) but still parallel to each other. In some embodiments, a first distance S3 is between the boiler plate 302 and a side of the piezoelectric unit 40a that is adjacent to the boiler plate 302, a first distance S3′ is between the boiler plate 302 and a side of the piezoelectric unit 40b that is adjacent to the boiler plate 302, and a first distance S3″ is between the boiler plate 302 and a side of the piezoelectric unit 40c that is adjacent to the boiler plate 302. The first distances S3, S3′, S3″ may be substantially equal to or not equal to each other (which will be described later). Hence, in some embodiments, the bubbles 500 may be controllably guided to flow along a specific direction or to specific locations.

Please refer to FIG. 4, FIG. 5C, and FIG. 5D at the same time. FIG. 5C and FIG. 5D respectively illustrate schematic views in the third view (i.e., the XY plane) according to a third embodiment and a fourth embodiment of the partial section B shown in FIG. 4 (to illustrate each of the embodiments more clearly, in the instant disclosure, the numerals of the piezoelectric units 40a, 40b, 40c, the boiler plates 302, and the channels T, T′ are omitted and not further illustrated in FIG. 5C and FIG. 5D). In some embodiments, the piezoelectric units 40a, 40b, 40c (or the channels T, T′) are gradually expanding or tapered along a direction away from the boiler plate 302. In FIG. 5C and FIG. 5D, a width at a side of the piezoelectric units 40b, 40c that is adjacent to the boiler plate 302 is an overall width S2, and a width at the other side of the piezoelectric units 40a, 40b, 40c that is away from the boiler plate 302 is an overall width S2′. The overall widths S2, S2′ may be substantially equal to or not equal to each other. For example, in the embodiments shown in FIG. 5C, the overall width S2′ is greater than the overall width S2. Hence, the piezoelectric units 40a, 40b, 40c (or the channels T, T′) are gradually expanding along a direction away from the boiler plate 302. In these cases, the bubbles 500 may be more efficiently guided to locations away from the boiler plate 302 along the channels T, T′ that are gradually expanding. For another example, in the embodiments shown in FIG. 5D, the overall width S2′ is less than the overall width S2. Hence, the piezoelectric units 40a, 40b, 40c (or the channels T, T′) are gradually tapered along a direction away from the boiler plate 302. In these cases, the bubbles 500 may be more collectively guided along the channels T, T′ that are gradually tapered to further flow along a specific direction, so that the bubbles 500 may be controllably guided to flow along a specific direction.

Please refer to FIG. 4 and FIG. 5E at the same time. FIG. 5E illustrates a schematic view in the third view (i.e., the XY plane) according to a fifth embodiment of the partial section B shown in FIG. 4 (to illustrate each of the embodiments more clearly, in the instant disclosure, the numerals of the piezoelectric units 40a, 40b, 40c, the boiler plate 302, and the channels T, T′ are omitted and not further illustrated in FIG. 5E). In some embodiments, the boiler plate 302 has a plate with W1 (e.g., the width along the X direction as shown in FIG. 3 or FIG. 5A), and the overall widths S2, S2′ may be independently greater than, less than, or substantially equal to the plate with W1. For example, in FIG. 5E, the overall width S2 (which may be referred to FIG. 5C and FIG. 5D and thus not further denoted in FIG. 5E) and the overall width S2′ are both greater than the plate width W1. Therefore, not only the bubbles 500 in the proximity of the boiler plate 302 but also the bubbles 500 at the bracket 308 (and in the proximity of the bracket 308) may be all controllably guided to flow away from the proximity of the boiler plate 302.

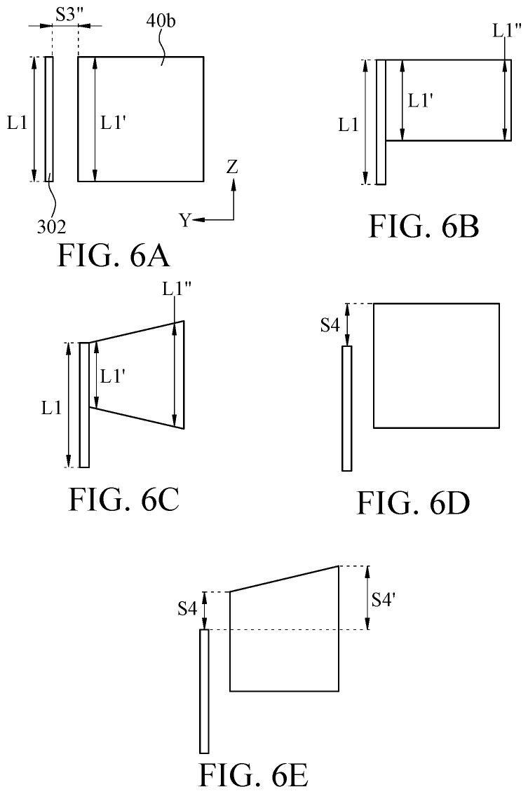

Please refer to FIG. 4 and FIG. 6A to FIG. 6C. FIG. 6A to FIG. 6C respectively illustrate schematic views in the second view (i.e., the YZ plane) according to a first embodiment to a third embodiment of the partial section B shown in FIG. 4 (to illustrate each of the embodiments more clearly, in the instant disclosure, only the piezoelectric unit 40b, the boiler plate 302, and the numerals of the piezoelectric units 40b and the boiler plates 302 are shown in FIG. 6A; the numerals of the piezoelectric units 40b and the boiler plates 302 are omitted and not further illustrated in FIG. 6B and FIG. 6C). In some embodiments, the boiler plate 302 has a plate length L1 (e.g., the length along the Z direction as shown in FIG. 3 or FIG. 6A). A length at a side of the piezoelectric units 40a, 40b, 40c that is adjacent to the boiler plate 302 is an overall length L1′, and a length at the other side of the piezoelectric units 40a, 40c that is away from the boiler plate 302 is an overall length L1″. The overall lengths L1′, L1″ may be independently greater than, less than, or substantially equal to the plate length L1. In other words, the overall lengths L1′, L1″ may be substantially equal to or not equal to each other.

In some embodiments, as shown in FIG. 6A, the plate length L1 of the boiler plate 302 is substantially equal to the overall lengths L1′, L1″ of the piezoelectric units 40a, 40b, 40c. Hence, in some embodiments, the bubbles 500 in the proximity of the boiler plate 302 may be efficiently guided to flow away from the proximity of the boiler plate 302. In some embodiments, as shown in FIG. 6B, the plate length L1 of the boiler plate 302 is not equal to the overall lengths L1′, L1″ of the piezoelectric units 40a, 40b, 40c, but the overall lengths L1′, L1″ are substantially equal to each other. In some embodiments, as shown in FIG. 6C, the plate length L1 of the boiler plate 302 is not equal to the overall lengths L1′, L1″ of the piezoelectric units 40a, 40b, 40c, and the overall lengths L1′, L1″ are not equal to each other. For example, in FIG. 6C, the overall length L1′ is less than overall length L1″, thereby forming the piezoelectric unit 40b in a roughly trapezoidal shape. Hence, in some embodiments, the bubbles 500 in the proximity of the upper side of the boiler plate 302 (and even the bubbles 500 slightly away from the boiler plate 302) can be particularly guided, so that the limited energy can be applied to the locations where the bubbles 500 in a large amount flow. Therefore, in some embodiments, a cooling performance of the boiler plate 302 at a certain level can be provided merely by utilizing the limited energy.

Please refer to FIG. 4, FIG. 6D, and FIG. 6E. FIG. 6D and FIG. 6E respectively illustrate schematic views in the second view (i.e., the YZ plane) according to a fourth embodiment and a fifth embodiment of the partial section B shown in FIG. 4 (to illustrate each of the embodiments more clearly, in the instant disclosure, the numerals of the piezoelectric unit 40b and the boiler plates 302 are omitted and not further illustrated in FIG. 6D and FIG. 6E). In some embodiments, vertical heights (e.g., the heights along the Z direction as shown in FIG. 3 or FIG. 6A) of the piezoelectric units 40a, 40b, 40c are substantially equal to each other, which may be also referred to FIG. 2 and FIG. 3. In some embodiments, the vertical heights of the piezoelectric units 40a, 40b, 40c are not lower than the vertical height of the boiler plate 302. In FIG. 6D and FIG. 6E, a second distance S4 is a distance between the upper side of the boiler plate 302 and the upper side at a side of the piezoelectric units 40a, 40b, 40c that is adjacent to the boiler plate 302, and a second distance S4′ is a distance between the upper side of the boiler plate 302 and the upper side at the other side of the piezoelectric units 40a, 40c that is away from the boiler plate 302. The second distances S4, S4′ may be independently greater than, less than, or substantially equal to zero. In other words, the upper side (i.e., the vertical height) at a side of the piezoelectric units 40a, 40b, 40c that is adjacent to the boiler plate 302 may be lower than, higher than, or substantially aligned with the upper side (i.e., the vertical height) of the boiler plate 302; meanwhile, the upper side (i.e., the vertical height) at a side of the piezoelectric units 40a, 40b, 40c that is away from the boiler plate 302 may be lower than, higher than, or substantially aligned with the upper side (i.e., the vertical height) of the boiler plate 302.

In some embodiments, as shown in FIG. 6D, the second distances S4, S4′ are greater than zero and substantially equal to each other. In some embodiments, as shown in FIG. 6E, the second distances S4, S4′ are greater than zero and the second distance S4′ is greater than second distance S4. Hence, each of the piezoelectric units 40a, 40b, 40c may be formed in a roughly trapezoidal shape and the upper side of each of piezoelectric units 40a, 40b, 40c may be higher than the upper side of the boiler plate 302. Therefore, in some embodiments, the bubbles 500 in the proximity of the upper side of the boiler plate 302 (and even the bubbles 500 slightly away from the boiler plate 302) can be particularly guided, so that the limited energy can be applied to the locations where the bubbles 500 in a large amount flow. Therefore, in some embodiments, a cooling performance of the boiler plate 302 at a certain level can be provided merely by utilizing the limited energy.

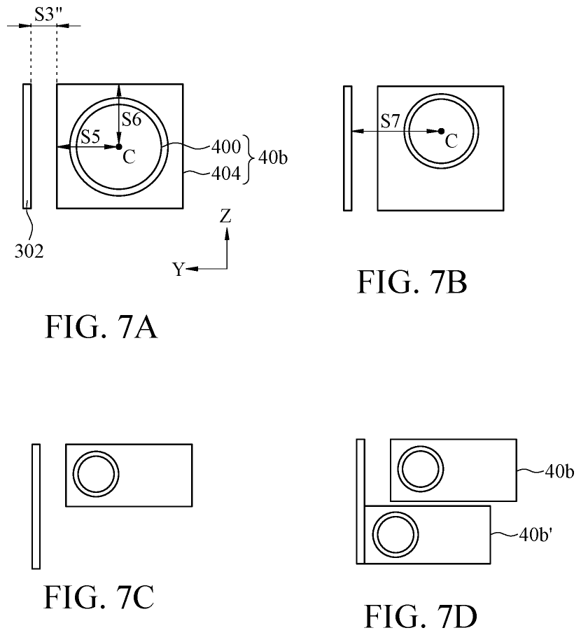

Please refer to FIG. 4, FIG. 7A, and FIG. 7B. FIG. 7A and FIG. 7B respectively illustrate schematic views in the second view (i.e., the YZ plane) according to a sixth embodiment and a seventh embodiment of the partial section B shown in FIG. 4 (to illustrate each of the embodiments more clearly, in the instant disclosure, only the piezoelectric unit 40b, the boiler plate 302, and the numerals of the piezoelectric unit 40b and the boiler plate 302 are shown in FIG. 7A; the numerals of the piezoelectric unit 40b and the boiler plate 302 are omitted and not further illustrated in FIG. 7B). In some embodiments, a first distance S3 is a distance between the boiler plate 302 and a side of the piezoelectric unit 40a that is adjacent to the boiler plate 302, a first distance S3″ is a distance between the boiler plate 302 and a side of the piezoelectric unit 40b that is adjacent to the boiler plate 302, and a first distance S3′ is a distance between the boiler plate 302 and a side of the piezoelectric unit 40c that is adjacent to the boiler plate 302. It is noted that only the first distance S3″ is illustrated in FIG. 7A and the corresponding first distances S3, S3′, S3″ may be referred to FIG. 5B. In some embodiments, each of the piezoelectric units 40a, 40b, 40c comprises a piezoelectric frame 404 and at least one acting section 400. In some embodiments, the shape of the acting section 400 may be, but not limited, a circle, an ellipse, a polygon, or any other shape. In the instant disclosure, the acting section 400 is illustrated as a circular acting section 400 for exemplified illustration, which is not used to limit the invention particularly to these specific embodiments. Take the piezoelectric unit 40b as an example, a third distance S5 is a distance between a center C of the acting section 400 and a side of the piezoelectric frame 404 that is adjacent to the boiler plate 302. A fourth distance S6 is a distance between the center C of the acting section 400 and the upper side of the piezoelectric frame 404. A fifth distance S7 is a distance between the center C of the acting section 400 and the boiler plate 302. For example, as shown in FIG. 7A, the fifth distance S7 is the sum of the first distance S3″ and the third distance S5. In some embodiments, the fifth distance S7 may be, but not limited to, any value ranging between 20 mm and 40 mm. In some embodiments, the third distance S5 and the fourth distance S6 of the piezoelectric unit 40b (as well as the piezoelectric units 40a, 40c) may be substantially equal to or not equal to each other. In other words, the first distances S3, S3″, S3′ of the piezoelectric units 40a, 40b, 40c may be substantially equal to or not equal to each other. The third distances S5 of the piezoelectric units 40a, 40b, 40c may be substantially equal to or not equal to each other. The fourth distance S6 of the piezoelectric units 40a, 40b, 40c may be substantially equal to or not equal to each other. The fifth distance S7 of the piezoelectric units 40a, 40b, 40c may be substantially equal to or not equal to each other.

In some embodiments, as shown in FIG. 7A, the third distance S5 and the fourth distance S6 are substantially equal to each other; therefore, the acting section 400 is substantially at the center of the piezoelectric frame 404. In some embodiments, as shown in FIG. 7B, the third distance S5 is substantially greater than the fourth distance S6; therefore, the acting section 400 is substantially at the location adjacent to the upper side of the piezoelectric frame 404. Hence, in some embodiments, through various configurations of the locations of the acting section 400, the bubbles 500 at specific locations can be particularly guided. Therefore, the limited energy can be utilized more efficiently, thereby reaching a cooling performance of the boiler plate 302 at a certain level.

Please refer to FIG. 7C and FIG. 7D. FIG. 7C and FIG. 7D respectively illustrate schematic views in the second view (i.e., the YZ plane) according to an eighth embodiment and a ninth embodiment of the partial section B shown in FIG. 4 (to illustrate each of the embodiments more clearly, in the instant disclosure, the numerals of the piezoelectric unit 40b and the boiler plates 302 are omitted and not further illustrated in FIG. 7C and FIG. 7D). In some embodiments, as shown in FIG. 7C, the piezoelectric frame 404 is configured to be adjacent to the upper side of the boiler plate 302 and the acting section 400 is configured to be adjacent to the boiler plate 302. Hence, in some embodiments, the bubbles 500 at the upper side of the boiler plate 302 and adjacent to the boiler plate 302 can be particularly guided, so that the limited energy can be applied to the locations where the bubbles 500 in a large amount flow. Therefore, a cooling performance of the boiler plate 302 at a certain level can be provided merely by utilizing the limited energy. Compared to FIG. 7C, in some embodiments, as shown in FIG. 7D, a plurality of piezoelectric units 40b, 40b′ are configured together at the same plane (e.g., the YZ plane as shown in FIG. 3 or FIG. 7A). The first distance S3″, the third distance S5, the fourth distance S6, and the fifth distance S7 of each of the piezoelectric units 40b, 40b′ may be respectively referred to the implementations described above, which will not be described in detail herein. In some embodiments, as shown in FIG. 7D, the piezoelectric unit 40b is configured at the upper side of the boiler plate 302, the piezoelectric unit 40b′ is configured to be adjacent to the lower side of the boiler plate 302, and the fifth distance S7 of the piezoelectric unit 40b is greater than the fifth distance S7 of the piezoelectric unit 40b′. Hence, in some embodiments, the bubbles 500 at specific locations or flowing along a specific streamline may be guided by the same plane (e.g., the YZ plane as shown in FIG. 7A). Therefore, the limited energy can be utilized more efficiently, thereby reaching a cooling performance of the boiler plate 302 at a certain level.

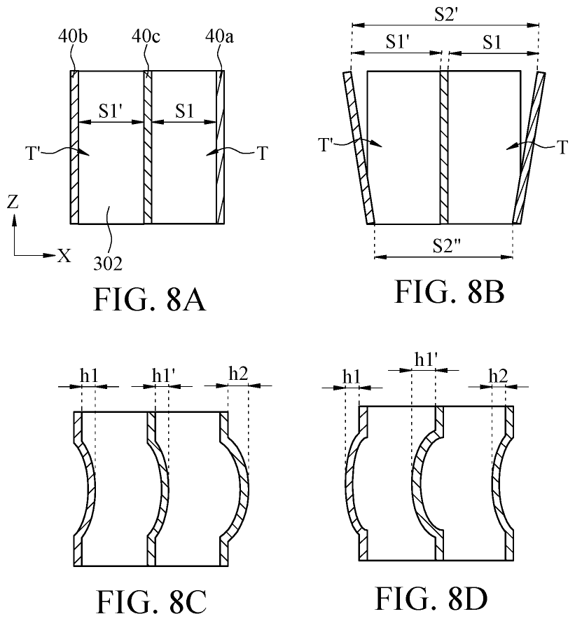

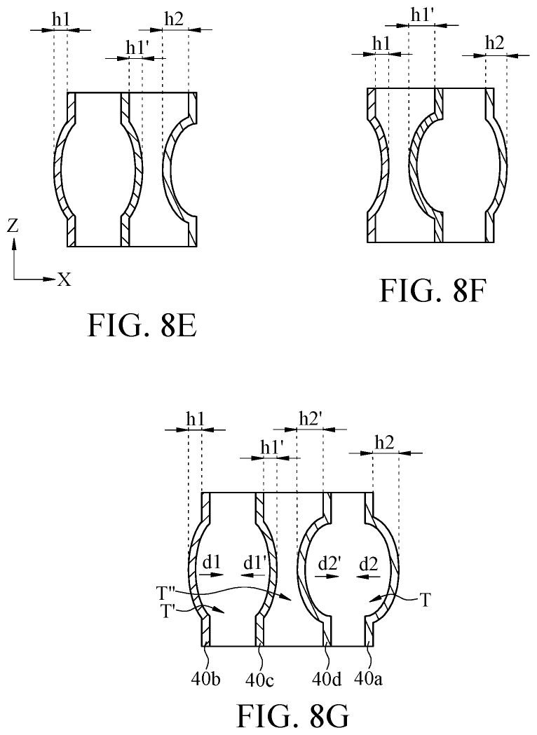

Please refer to FIG. 4, FIG. 8A, and FIG. 8B. FIG. 8A and FIG. 8B respectively illustrate schematic views in the first view (i.e., the XZ plane) according to a first embodiment and a second embodiment of the partial section B shown in FIG. 4 (to illustrate each of the embodiments more clearly, in the instant disclosure, only the piezoelectric units 40a, 40b, 40c, the boiler plate 302, and the numerals of the piezoelectric units 40a, 40b, 40c and the boiler plate 302 are shown in FIG. 8A; the numerals of the piezoelectric units 40a, 40b, 40c and the boiler plate 302 are omitted and not further illustrated in FIG. 8B). In FIG. 8A and FIG. 8B, a width at a side of the piezoelectric units 40a, 40b, 40c that is adjacent to the lower side of the boiler plate 302 is an overall width S2″, and a width at the other side of the piezoelectric units 40b, 40c that is adjacent to the upper side of the boiler plate 302 is an overall width S2′. The overall widths S2″, S2′ may be independently greater than, less than, or substantially equal to the plate width W1 (as shown in FIG. 5E). In other words, the overall widths S2″, S2′ may be substantially equal to or not equal to each other. In FIG. 8A, the overall widths S2″, S2′ are substantially equal to the plate width W1. In FIG. 8B, the overall width S2′ (which is adjacent to the upper side of the boiler plate 302) is greater than the overall width S2″ (which is adjacent to the lower side of the boiler plate 302). Hence, the piezoelectric units 40a, 40b, (or the channels T, T′) are gradually expanding upwards along a vertical direction (e.g., the upward direction as shown in FIG. 8B; or the +Z direction as shown in FIG. 3 or FIG. 8A). Therefore, in these cases, the bubbles 500 can be more efficiently guided to locations away from the boiler plate 302 along the channels T, T′ that are gradually expanding.

Please refer to FIG. 4, FIG. 8C, and FIG. 8D. FIG. 8C and FIG. 8D respectively illustrate schematic working views in the first view (i.e., the XZ plane) according to a third embodiment and a fourth embodiment of the partial section B shown in FIG. 4 (to illustrate each of the embodiments more clearly, in the instant disclosure, the numerals of the piezoelectric units 40a, 40b, 40c and the boiler plates 302 are omitted and not further illustrated in FIG. 8C and FIG. 8D). When each of the piezoelectric units 40a, 40b, 40c is driven, each of the piezoelectric units 40a, 40b, 40c may further generate a deformation. Each of the piezoelectric units 40a, 40b, 40c may be driven by the piezoelectric driver 42 to generate a deformation in a reciprocating manner along an axial direction. In some embodiments, as shown in FIG. 8C, the piezoelectric units 40a, 40b, 40c are configured to be parallel to each other, and the axial direction of the deformations of the piezoelectric units 40a, 40b, 40c (e.g., the horizontal direction as shown in FIG. 8C; i.e., the X direction as shown in FIG. 8A) are substantially identical to each other. In some embodiments, the piezoelectric units 40a, 40b, may be driven by the piezoelectric driver 42 to synchronously generate deformations toward one direction (e.g., the +X direction as shown in FIG. 8A and FIG. 8C) and then synchronously generate deformations toward another direction (e.g., the −X direction as shown in FIG. 8A and FIG. 8D). Next, the piezoelectric units 40a, 40b, 40c are repeatedly driven by the piezoelectric driver 42 according to the above steps. The direction and the another direction are in opposite directions but correspond to the axial direction. Therefore, disturbances in the channels T, T′ may be generated by the piezoelectric units 40a, 40b, 40c, which is helpful for the bubbles 500 to leave from the boiler plate 302.

Please refer to FIG. 4, FIG. 8E, and FIG. 8F. FIG. 8E and FIG. 8F respectively illustrate schematic working views in the first view (i.e., the XZ plane) according to a fifth embodiment and a sixth embodiment of the partial section B shown in FIG. 4 (to illustrate each of the embodiments more clearly, in the instant disclosure, the numerals of the piezoelectric units 40a, 40b, 40c and the boiler plates 302 are omitted and not further illustrated in FIG. 8E and FIG. 8F). In some embodiments, the piezoelectric units 40a, 40b, 40c are non-synchronously driven by the piezoelectric driver 42. For example, at a first timing, a first piezoelectric unit 40a and a second piezoelectric unit 40b are driven by the piezoelectric driver 42 to synchronously deform toward an identical direction (e.g., the +X direction as shown in FIG. 8E), and a third piezoelectric unit 40c is driven by the piezoelectric driver 42 to deform toward another direction (e.g., the −X direction as shown in FIG. 8E). Then, at a next timing, the first piezoelectric unit 40a and the second piezoelectric unit 40b are driven by the piezoelectric driver 42 to synchronously deform toward the another direction (e.g., the −X direction as shown in FIG. 8E and FIG. 8F), and the third piezoelectric unit 40c is driven by the piezoelectric driver 42 to deform toward the direction (e.g., the +X direction as shown in FIG. 8E and FIG. 8F). Next, the piezoelectric units 40a, 40b, 40c are repeatedly driven by the piezoelectric driver 42 according to the above steps. The direction and the another direction are in opposite directions but correspond to the axial direction. Therefore, the inward-shrinking and outward-expanding deformations of each of the channels T, T′ may be generated by the piezoelectric units 40a, 40b, 40c, so that the capacities of the channels T, T′ may be changed to shrink and expand in a reciprocating manner with time. Hence, the disturbance applied on the heat transfer fluid 50 may be enhanced, so that the bubbles 500 can leave from the surface of the boiler plate 302 more quickly.

In some embodiments, the driving of non-synchronously deforming may be conducted by making the first piezoelectric unit 40a, the second piezoelectric unit 40b, and the third piezoelectric unit 40c sequentially deform toward an identical direction and then sequentially deform toward another direction. Alternatively, in some embodiments, each of the piezoelectric units 40a, 40b, 40c may be randomly driven to deform toward specific directions at any time. Hence, the disturbance applied on the heat transfer fluid 50 can be enhanced by any of the above implementations to further allow the bubbles 500 to leave from the surface of the boiler plate 302 more quickly.

Please refer to FIG. 8G. FIG. 8G illustrates a schematic working view in the first view (i.e., the XZ plane) according to a seventh embodiment of the partial section B shown in FIG. 4 (to illustrate each of the embodiments more clearly, in the instant disclosure, the numeral of the boiler plate 302 is omitted and not further illustrated in FIG. 8G). In some embodiments, as shown in FIG. 8G, the two adjacent piezoelectric units (e.g., the first piezoelectric unit 40a and the fourth piezoelectric unit 40d; or the second piezoelectric unit 40b and the third piezoelectric unit 40c) are synchronously driven to further deform toward opposite directions. Hence, the efficacies of the implementations as shown in FIG. 8G similar to those of the implementations as shown in FIG. 8E and FIG. 8F can be achieved, and thus will not be further described herein.

Please still refer to FIG. 8G. Take the embodiments as shown in FIG. 8G as an example, the deformation of the piezoelectric unit 40a has a deformation direction d2, the deformation of the piezoelectric unit 40b has a deformation direction d1, the deformation of the piezoelectric unit 40c has a deformation direction d1′, and the deformation of the piezoelectric unit 40d has a deformation direction d2′. Each of the deformed piezoelectric units 40a, 40b, 40d roughly has a bow shape. Each of the deformation directions d2, d1, d1′, d2′ refers to a direction that passes through the midpoint of a virtual line that connects two endpoints of the bow and that is away from the corresponding one of the piezoelectric units 40a, 40b, 40c, 40d. In some embodiments, when the two adjacent piezoelectric units 40a, 40d (or the two adjacent piezoelectric units 40b, 40c) are driven, the deformation directions d2, d2′ of the two adjacent piezoelectric units 40a, 40d are meanwhile in opposite directions (or the deformation directions d1, d1′ of the two adjacent piezoelectric units 40a, 40c are meanwhile in opposite directions; or the deformation directions d1′, d2′ of the two adjacent piezoelectric units 40c, are meanwhile in opposite directions). Hence, as shown in FIG. 8G, the two adjacent piezoelectric units 40a, 40d have a channel T″ with a narrower width; therefore, the bubbles 500 in the channel T″ can escape to leave from the boiler plate 302 more quickly. The two adjacent piezoelectric units 40b, 40c (or the two adjacent piezoelectric units 40a, 40d) have a channel T′ (or channel T) with a wider width; therefore, the bubbles 500 may flow quickly to be collected in the channel T′ (or channel T). In some embodiments, with the assistance of the piezoelectric driver 42, through intermittently or periodically applying the electric potential difference with various driving frequencies (which may be, but not limited to 2.4±0.5 kHz) to the piezoelectric units 40a, 40b, 40c, 40d, the piezoelectric units 40a, 40b, 40c, 40d may further deform in a reciprocating manner (e.g., the piezoelectric units 40a, 40b, 40c, 40d are deformed from FIG. 8A to FIG. 8G and then recovered from FIG. 8G to FIG. 8A). Therefore, in some embodiments, the bubbles 500 in a much larger amount may be intermittently or periodically forced to quickly leave from the boiler plate 302.

Please still refer to FIG. 8C, FIG. 8D, and FIG. 8G. In FIG. 8C and FIG. 8D, the piezoelectric units 40a, 40b, 40c (as shown in FIG. 8A) comprise a plurality of side piezoelectric units (e.g., the first piezoelectric unit 40a and the second piezoelectric unit 40b) at two sides of the piezoelectric units 40a, 40b, 40c and at least one middle piezoelectric unit (e.g., the third piezoelectric unit 40c) at the middle of the piezoelectric units 40a, 40b, 40c. The side piezoelectric unit (e.g., the first piezoelectric unit 40a) has a deformation extent h2, the side piezoelectric unit (e.g., the first piezoelectric unit 40b) has a deformation extent h1, and the middle piezoelectric unit (e.g., the third piezoelectric unit 40c) has a deformation extents h1′. The deformation extents h2, h1, h1′ are substantially equal to or not equal to each other. Each of the deformation extents h2, h1, h1′ refers to a distance between the bow of the deformation and a point of the deformation, where the point of the deformation is a point that is farthest from the bow. For example, in the embodiments, as shown in FIG. 8C, the deformation extent h1 of the side piezoelectric unit 40b and the deformation extent h1′ of the middle piezoelectric unit are both less than the deformation extent h2 of the side piezoelectric unit 40a. For another example, in the embodiments, as shown in FIG. 8D, the deformation extent h1′ of the middle piezoelectric unit 40c is greater than the deformation extents h2, h1 of the side piezoelectric units 40a, 40b. In FIG. 8G, at least one middle piezoelectric unit (e.g., the third piezoelectric unit 40c and the fourth piezoelectric unit 40d) is between the side piezoelectric units (e.g., the first piezoelectric unit 40a and the second piezoelectric unit 40b) at two sides of the piezoelectric units 40a, 40b, 40c. The deformation directions d1, d1′ (or the deformation directions d1′, d2′; or the deformation direction d2′, d2) of the two adjacent piezoelectric units 40c (or the two adjacent piezoelectric units 40c, 40d; or the two adjacent piezoelectric units 40d, 40a) are in opposite directions. The side piezoelectric units (e.g., the first piezoelectric unit 40a and the second piezoelectric unit 40b) and the two middle piezoelectric units (e.g., the third piezoelectric unit 40c and the fourth piezoelectric unit 40d) respectively have deformation extents h2, h1, h1′, h2′ substantially equal to or not equal to each other. Hence, in some embodiments, by adjusting each of the deformation extents h2, h1, h1′, h2′ of the piezoelectric units 40a, 40b, 40c, 40d and the combination of the deformation extents h2, h1, h1′, h2′, various combinations of deformations in a reciprocating manner and corresponding control effects of the bubbles 500 can be provided.

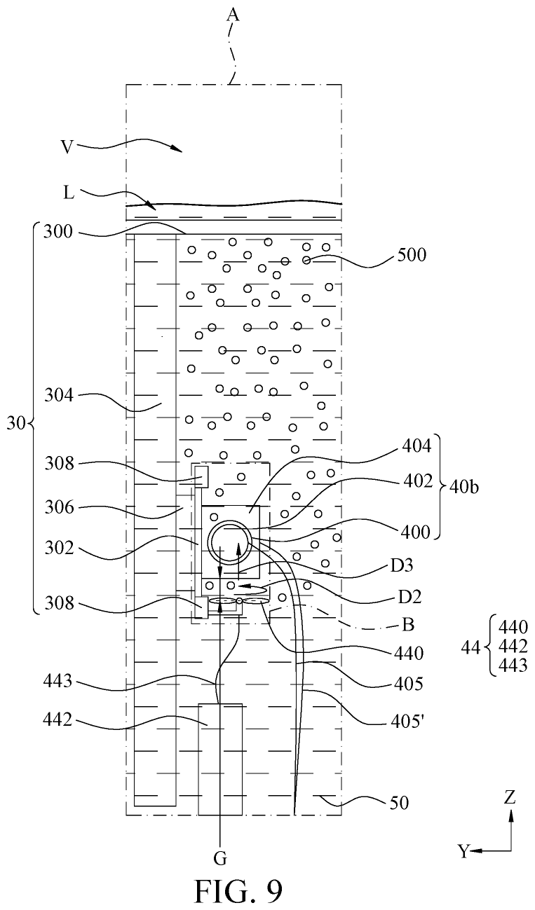

Please refer to FIG. 9. FIG. 9 illustrates a schematic working view in the second view (i.e., the YZ plane) of a partial section A of a single immersion unit 30 of the immersion cooling system 10 according to some embodiments. In some embodiments, the immersion unit 30 further comprises a disturbing element 44 adjacent to the piezoelectric units 40a, 40b, (it is noted that the piezoelectric units 40a, 40c are omitted and not further denoted in FIG. 9). Hence, in some embodiments, through the configuration of the disturbing element 44, the flowing velocity of the bubbles 500 in the channels T, T′ can be enhanced. In FIG. 9, according to some embodiments, the disturbing element 44 is adjacent to the piezoelectric unit but away from the surface of the heat transfer fluid 50. In some embodiments, a disturbing distance G is a distance between the disturbing element 44 and the lower side of the piezoelectric units 40a, 40b, 40c. The disturbing distance G may be, but not limited to, any value ranging between 10 mm and 20 mm. The disturbing element 44 comprises a rotation-disturbing element 440 and a rotation-disturbing driver 442. The rotation-disturbing element 440 is driven by the rotation-disturbing driver 442 to generate a disturbance in a direction toward the piezoelectric unit 40b (i.e., the third direction D3 as shown in FIG. 9). In FIG. 9, the third direction D3 is substantially parallel to a direction (i.e., the first direction D1 as shown in FIG. 9) that the overall bubbles 500 flow to the surface of the heat transfer fluid 50. In some embodiments, the rotation-disturbing element 440 may be a fan or other disturbing units with fan blades. The rotation-disturbing element 440 is electrically connected to the rotation-disturbing driver 442 through a rotation-disturbing wire 443, so that the rotation-disturbing element 440 is driven by the rotation-disturbing driver 442 to further rotate along the second direction D2 (which may be counterclockwise or clockwise). Therefore, in some embodiments, through a manner of rotation disturbance, the flowing velocity of the bubbles 500 in the channels T, T′ can be enhanced.

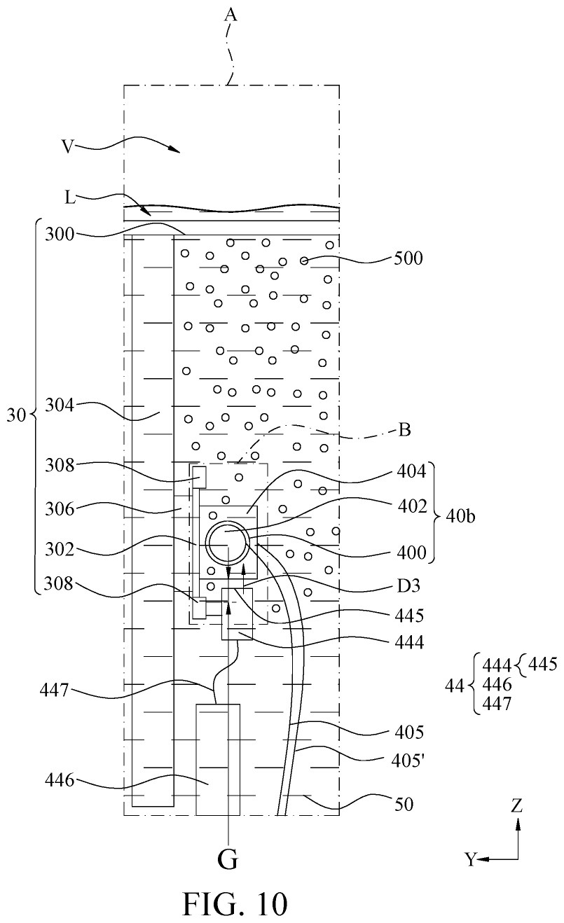

Please refer to FIG. 10. FIG. 10 illustrates a schematic working view in the second view (i.e., the YZ plane) of a partial section A of a single immersion unit 30 of the immersion cooling system 10 according to some embodiments. In some embodiments, as shown in FIG. 10, the disturbing unit 44 is adjacent to the piezoelectric unit 40b but away from the surface of the heat transfer fluid 50. In some embodiments, a disturbing distance G is a distance between the disturbing unit 44 and the lower side of the piezoelectric units 40a, 40b, 40c. The disturbing distance G may be, but not limited to, any value ranging between 10 mm and 20 mm. The disturbing unit 44 comprises a jetting element 444 and a jetting driver 446. The jetting element 444 is driven by the jetting driver 446 to generate a disturbance in a direction toward the piezoelectric unit 40b (i.e., the third direction D3 as shown in FIG. 10). In FIG. 10, the third direction D3 is substantially parallel to a direction (i.e., the first direction D1 as shown in FIG. 2 and FIG. 10) that the overall bubbles 500 flow to the surface of the heat transfer fluid 50. In some embodiments, the jetting element 444 may be a disturbing element capable of generating a jet flow. For example, in FIG. 10, the jetting element 444 is a disturbing element having a nozzle 445. The jetting element 444 is electrically connected to the jetting driver 446 through a jetting wire 447, so that the jetting element 444 is driven by the jetting driver 446 to further generate a disturbance along the third direction D3 through the nozzle 445. Therefore, in some embodiments, through a manner of jet-flow disturbance, the flowing velocity of the bubbles 500 in the channels T, T′ can be enhanced.

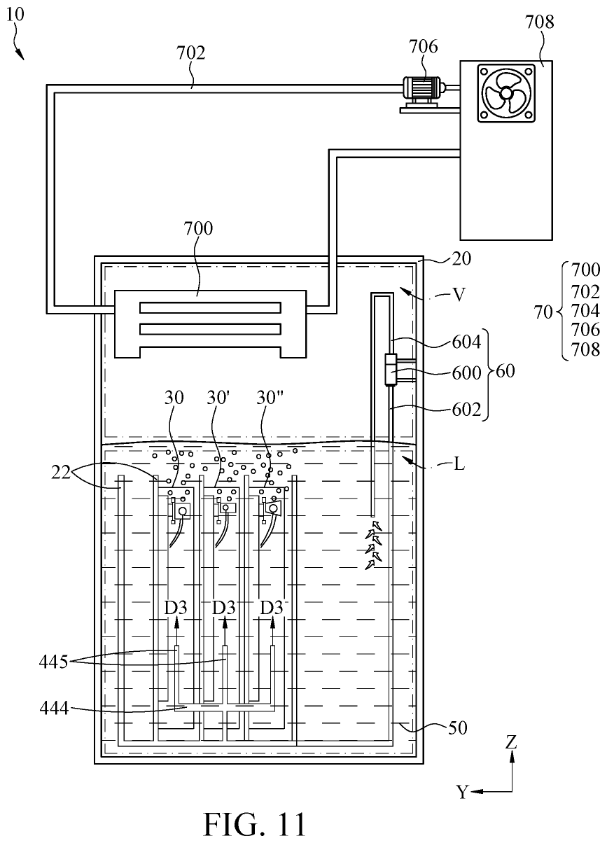

Please refer to FIG. 11. FIG. 11 illustrates a schematic working view of a plurality of immersion units 30, 30′, 30″ of the immersion cooling system 10 according to some embodiments. In some embodiments, as shown in FIG. 11, the immersion cooling system 10 comprises a plurality of cabinets 22 (or a plurality of cooling tanks 20) and a plurality of immersion units 30, 30′, 30″. Each of the cooling tanks 20 corresponds to a corresponding one of the immersion units 30, 30′, 30″. Each of the immersion units 30, 30′, 30″ corresponds to corresponding a plurality of piezoelectric units 40a, 40b, 40c (not denoted in FIG. 11 but can be referred to FIG. 2) and a corresponding one of the piezoelectric drivers 42 (not denoted in FIG. 11 but can be referred to FIG. 2). The immersion units 30, 30′, 30″ and the elements thereof may respectively correspond to the immersion units 30 and the elements thereof mentioned in the aforementioned embodiments, which will not be described in detail herein. Hence, in some embodiments, much more elements and devices to be cooled can be quickly cooled in the limited cooling space. Therefore, the heat transfer rate between the elements to be cooled and the heat transfer fluid 50 will not be apparently affected by the bubbles 500 in a large amount. Hence, in some embodiments, the utilization rate of the limited cooling space can be improved, and the elements and devices to be cooled can be configured more densely, thereby enhancing the working performance of the overall elements and devices (e.g., enhancing the overall power density).

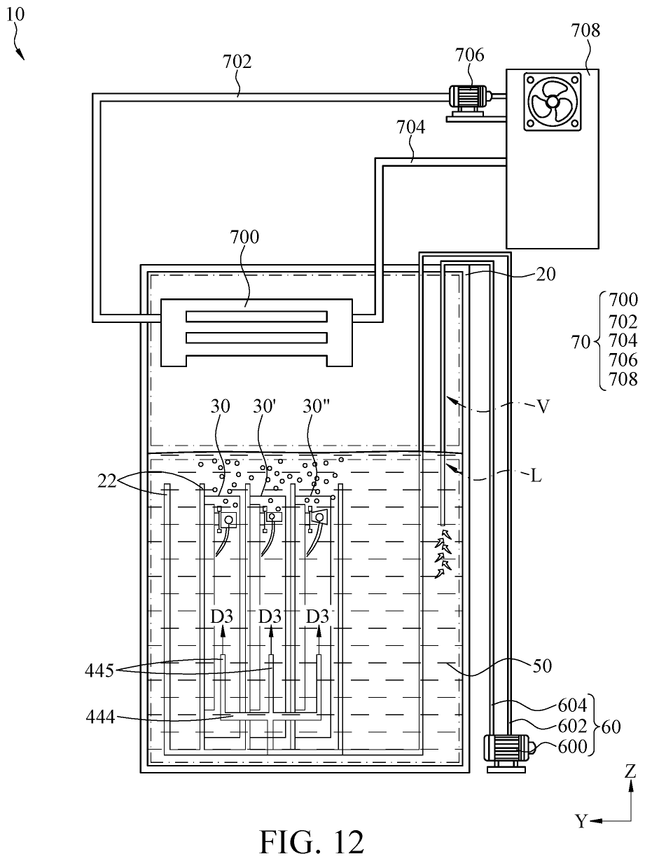

Please refer to FIG. 11 and FIG. 12. FIG. 12 illustrates a schematic working view of a plurality of immersion units 30, 30′, 30″ of the immersion cooling system 10 according to some embodiments. In the embodiments, as shown in FIG. 11 and FIG. 12, a plurality of immersion units 30, 30′, 30″ may share the same disturbing unit 44 (not further denoted in FIG. 11 and FIG. 12, but may be referred to in FIG. 10). For example, the disturbing unit 44 is a jetting element 444 having a plurality of nozzles 445. The nozzles 445 respectively correspond to the immersion units 30, 30′, 30″. Each of the nozzles 445 is driven by the jetting driver 446 (not further denoted in FIG. 11 and FIG. 12, but may be referred to in FIG. 10) to generate a disturbance in a direction toward the piezoelectric unit 40b (i.e., the third direction D3 shown in FIG. 11 and FIG. 12). Hence, efficiencies of removing the bubbles 500 in a plurality of the immersion units 30, 30′, 30″ can be synchronously enhanced, so that the heat transfer rates between the elements to be cooled and the heat transfer fluid 50 in the immersion units 30, 30′, 30″ can also be enhanced at the same time. In some embodiments, the immersion cooling system 10 further comprises a pump device 60. In FIG. 11 and FIG. 12, the pump device 60 has a jetting pump 600, a first pipeline 604, and a second pipeline 602. One end of the two ends of the first pipeline 604 is submerged by the surface of the heat transfer fluid 50. Both of the other end of the two ends of the first pipeline 604 and one end of the two ends of the second pipeline 602 are connected to the jetting pump 600. The other end of the two ends of the second pipeline 602 is connected to the jetting element 444. Hence, through the driving of the jetting pump 600, the heat transfer fluid 50 would be suctioned from the first pipeline 604 to pass through the second pipeline 602, and the heat transfer fluid 50 would be accelerated and discharged from the jetting element 444. In these cases, the jetting pump 600 may be configured to be inside the cooling tank 20 (e.g., as shown in FIG. 11) or outside the cooling tank 20 (e.g., as shown in FIG. 12). Therefore, the heat transfer fluid 50 away from the elements to be cooled and thus having a lower temperature can be suctioned. The suctioned heat transfer fluid 50 can further serve as the driving force of the acceleration of the bubbles 500 in the immersion units 30, 30′, 30″. Hence, the heat transfer rate between each of the elements to be cooled and the heat transfer fluid 50 can be more efficiently enhanced.

In some embodiments, the immersion cooling system 10 comprises a plurality of immersion units 30, 30′, 30″, which may be configured according to the implementations described in FIG. 11, FIG. 12, or any combination thereof, and thus more various assembly embodiments thereof can be provided. Even though the corresponding figures are not further illustrated herein, the above embodiments should all be included in the embodiments of the instant disclosure. Hence, in some embodiments, the utilization rate of the limited cooling space can be enhanced by the immersion cooling system 10, and the elements and devices to be cooled can be configured more densely. Therefore, the working performance of the overall elements and devices (e.g., enhancing the overall power density) can be enhanced.

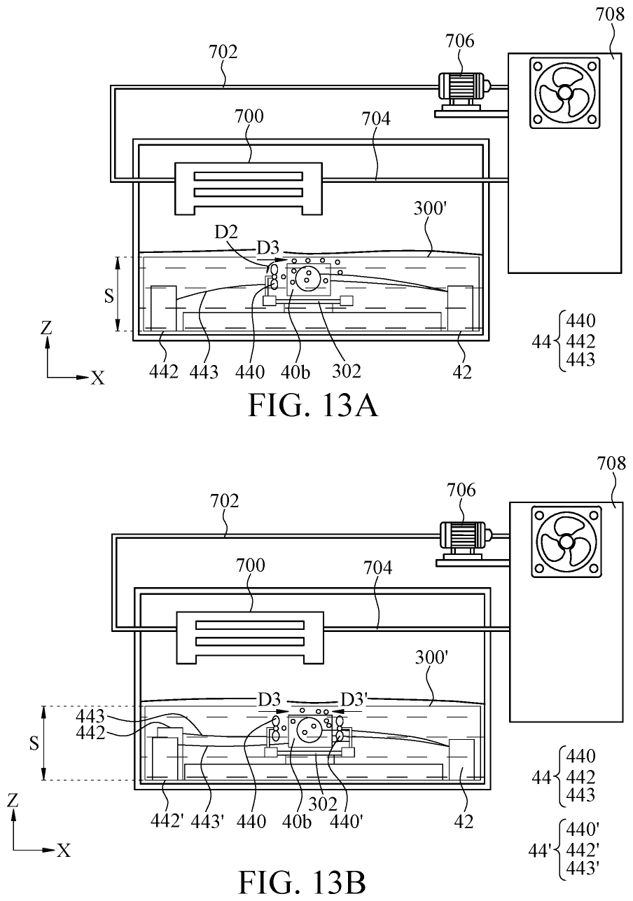

Please refer to FIG. 13A and FIG. 13B. FIG. 13A and FIG. 13b respectively illustrate schematic working views in the first view (i.e., the XZ plane) of a single immersion unit 30 of the immersion cooling system 10 according to some embodiments (to illustrate each of the embodiments more clearly, in the instant disclosure, the numerals of the immersion cooling system 10 and the immersion unit 30 are omitted and not further illustrated in FIG. 13A and FIG. 13B, and the other elements can be referred to the above implementations and will not be further denoted herein). In some embodiments, as shown in FIG. 16 and FIG. 17, the boiler plate 302 is substantially fixed to the main body frame 300′. The boiler plate 302 has a main surface, and the main surface is a surface contacting the heat transfer fluid 50. The main surface faces the surface of the heat transfer fluid 50 and is substantially parallel to the surface of the heat transfer fluid 50. Hence, in some embodiments, the direction that the bubbles 500 leave from the boiler plate 302 is substantially identical or similar to the direction that the bubbles 500 move to the gas-phase space V. Therefore, the boiler plate 302 may be extendingly configured along the direction (e.g., the X direction as shown in FIG. 13A) that is substantially parallel to the surface of the heat transfer fluid 50. Alternatively, in some embodiments, the boiler plate 302 may be extendingly configured along the plane (e.g., the XY plane as shown in FIG. 13A) that is substantially parallel to the surface of the heat transfer fluid Hence, the inner space of the immersion unit 30 may be utilized more sufficiently, thereby cooling more of the boiler plates 302 synchronously and more efficiently.

In FIG. 13A, according to some embodiments, the immersion unit 30 comprises a disturbing unit 44 adjacent to the piezoelectric unit 40b. For example, the disturbing unit 44 is on the bracket 308. A distance between the disturbing unit 44 and the piezoelectric unit 40b may be, but not limited to, any value ranging between 10 mm and 20 mm. In some embodiments, the disturbing unit 44 comprises a rotation-disturbing element 440 and a rotation-disturbing driver 442. The rotation-disturbing element 440 is driven by the rotation-disturbing driver 442 to generate a disturbance in a direction toward the piezoelectric unit 40b (i.e., the third direction D3 shown in FIG. 13A). In FIG. 13A, the third direction D3 is substantially parallel to the surface of the heat transfer fluid 50. In some embodiments, the rotation-disturbing element 440 may be a fan or other disturbing units with fan blades. The rotation-disturbing element 440 is electrically connected to the rotation-disturbing driver 442 through a rotation-disturbing wire 443, so that the rotating-disturbing element 440 is driven by the rotation-disturbing driver 442 to further rotate along the second direction D2 (which may be counterclockwise or clockwise). Therefore, in some embodiments, through a manner of rotation disturbance, the flowing velocity of the bubbles 500 in the channels T, T′ (which may be referred to FIG. 5A and thus not further denoted in FIG. 13A) can be enhanced.

In FIG. 13B, according to some embodiments, the immersion unit 30 comprises two disturbing units 44, 44′ respectively at two opposite sides of the piezoelectric unit 40b and adjacent to the piezoelectric unit 40b. A distance between the disturbing units 44 and the piezoelectric unit 40b and a distance between the disturbing units 44′ and the piezoelectric unit 40b may respectively be, but not limited to, any value ranging between 10 mm and 20 mm. In some embodiments, the disturbing unit 44 comprises the rotation-disturbing element 440 and the rotation-disturbing driver 442 corresponding to the rotation-disturbing element 440. The disturbing unit 44′ comprises the rotation-disturbing element 440′ and the rotation-disturbing driver 442′ corresponding to the rotation-disturbing element 440′. The rotation-disturbing elements 440, 440′ may respectively be a fan or other disturbing units with fan blades to be respectively driven by the rotation-disturbing drivers 442, 442′ to further rotate along the third directions D3, D3′. The third directions D3, D3′ may be identical or different from each other. For example, in FIG. 13B, the third directions D3, D3′ are in opposite directions but substantially parallel to the surface of the heat transfer fluid 50. Therefore, the bubbles 500 can be guided to and thus collected at a specific location to prevent the bubbles 500 from escaping to the other locations. Hence, the bubbles 500 can be ensured to escape through the specific locations to the gas-phase space V.

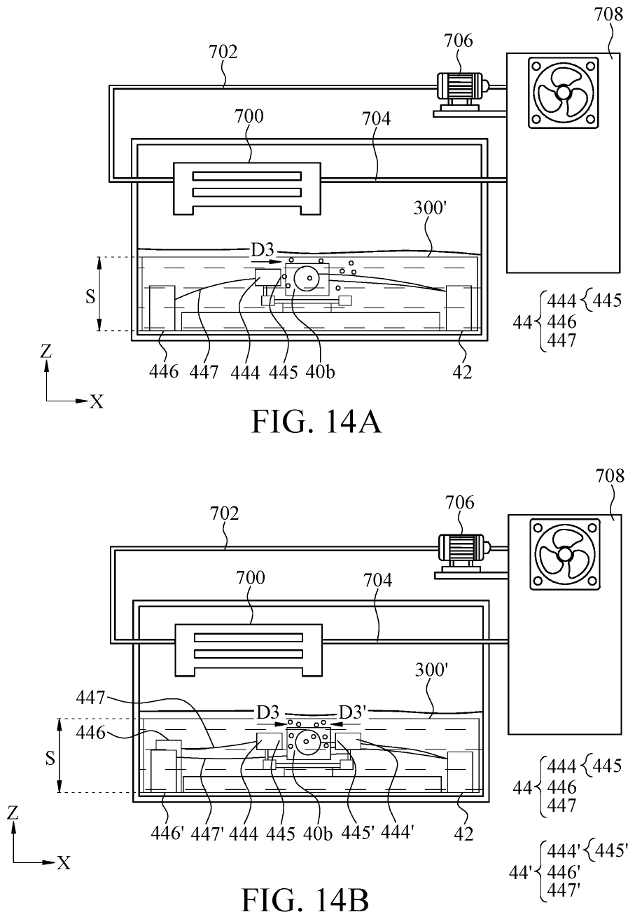

Please refer to FIG. 14A and FIG. 14B. FIG. 14A and FIG. 14B respectively illustrate schematic working views in the first view (i.e., the XZ plane) of a single immersion unit 30 of the immersion cooling system 10 according to some embodiments (to illustrate each of the embodiments more clearly, in the instant disclosure, the immersion cooling system 10 and the immersion unit 30 are not further shown in FIG. 14A and FIG. 14B, and the other elements can be referred to the above implementations, which will not be further described herein). In FIG. 14A, according to some embodiments, the immersion unit 30 comprises a disturbing unit 44 adjacent to the piezoelectric unit 40b. For example, the disturbing unit 44 is on the bracket 308. In some embodiments, the disturbing unit 44 comprises a jetting element 444 and a jetting driver 446. The jetting element 444 is driven by the jetting driver 446 to generate a disturbance in a direction toward the piezoelectric unit 40b (i.e., the third direction D3 shown in FIG. 14A). In FIG. 14A, the third direction D3 is substantially parallel to a direction of the surface of the heat transfer fluid 50. In some embodiments, the jetting element 444 may be a disturbing element capable of generating a jet flow. For example, in FIG. 14A, the jetting element 444 is a disturbing element having a nozzle 445. The jetting element 444 is electrically connected to the jetting driver 446 through a jetting wire 447, so that the jetting element 444 is driven by the jetting driver 446 to further generate a disturbance along the third direction D3 through the nozzle 445. Therefore, in some embodiments, through a manner of jet-flow disturbance, the flowing velocity of the bubbles 500 in the channels T, T′ (which may be referred to FIG. 5A and thus not further denoted in FIG. 14A) can be enhanced.

In FIG. 14B, according to some embodiments, the immersion unit 30 comprises two disturbing units 44, 44′ respectively at two opposite sides of the piezoelectric unit 40b and adjacent to the piezoelectric unit 40b. The disturbing unit 44 comprises the jetting element 444 and the jetting driver 446 corresponding to the jetting element 444. Likewise, the disturbing unit 44′ comprises the jetting element 444′ and the jetting driver 446′ corresponding to the jetting element 444′. Each of the jetting elements 444, 444′ may be a disturbing element having nozzles 445, 445′. The jetting element 444 is electrically connected to the jetting driver 446 through a jetting wire 447, so that the jetting element 444 is driven by the jetting driver 446 to further generate a disturbance along the third direction D3 through the nozzle 445. Likewise, the jetting element 444′ is electrically connected to the jetting driver 446′ through a jetting wire 447′, so that the jetting element 444′ is driven by the jetting driver 446′ to further generate a disturbance along the third direction D3′ through the nozzle 445′. The third directions D3, D3′ may be identical or different from each other. For example, in FIG. 14B, the third direction D3, D3′ are in opposite directions but substantially parallel to the surface of the heat transfer fluid 50. Therefore, the bubbles 500 may be guided to and thus collected at a specific location to prevent the bubbles 500 from escaping to the other locations. Hence, the bubbles 500 can be ensured to escape through the specific locations to the gas-phase space V.

In some embodiments, the immersion unit 30 comprises two or more disturbing units 44, 44′. The disturbing units 44, 44′ are at two opposite sides of the piezoelectric unit or adjacent to each other. Meanwhile, the disturbing units 44, 44′ are adjacent to the piezoelectric unit 40b. The disturbing units 44, 44′ may independently comprises the rotation-disturbing element 440 (which comprises the rotation-disturbing driver 442), the jetting element 444 (which comprises the jetting driver 446), or a combination of the rotation-disturbing element 440 and the jetting element 444. Hence, in some embodiments, through much more combinations and configurations of the disturbing units 44, 44′, the bubbles 500 can be guided to and thus collected at a specific location to prevent the bubbles 500 from escaping to the other locations. Therefore, the bubbles 500 can be ensured to escape through the specific locations to the gas-phase space V.

In some embodiments that the immersion unit 30 is a single rack-mounted server unit, still referring to FIG. 1A, the main body frame 300 of the immersion unit 30 is a closed-type frame and the main body frame 300 does not comprise a cabinet 22. At least one channel T (as shown in FIG. 5A) is between the piezoelectric units 40a, 40b, and the at least one channel is in communication with the boiler plate 302. The piezoelectric driver 42 is connected to the piezoelectric units 40a, 40b so as to drive the piezoelectric units 40a, 40b to respectively generate the deformations. The heating element 306 (as shown in FIG. 4) of the immersion unit 30 contacts the boiler plate 302. When the electronic device 304 is in operation, since the gas-phase heat transfer fluid 50 contacting the boiler plate 302 is vaporized by absorbing the heats, a large number of bubbles 500 vaporized from the gas-phase heat transfer fluid 50 would pass through and be guided by the deformable channel T between piezoelectric units 40a, 40b. Then, the bubbles 500 would further escape to the gas-phase space V and be condensed upon contacting the condenser 700 in the gas-phase space V. Hence, in some embodiments, through the guiding of the deformable channel T between piezoelectric units 40a, 40b, the heat transfer fluid 50 can be forced to leave from the boiler plate 302 more quickly, thereby enhancing the overall cooling performance of the heat transfer fluid 50. The elements described herein (which may further comprise, for example, the bracket 308, the condensation device 70, the first condensation pipe 702, the second condensation pipe 704, the condensation pump 706, and the heat exchanger 708) and the corresponding implementations thereof can all be referred to the above implementations, which will not be described in detail herein.

To sum up, in some embodiments, bubbles of the heat transfer fluid would be generated in operation. A plurality of piezoelectric units are configured in the proximity of the boiler plate, so the bubbles may flow to at least one channel formed between the piezoelectric units or in the proximity of the piezoelectric units. Since the at least one channel would be deformed by the piezoelectric units when the corresponding piezoelectric units are applied with an electric potential difference, the bubbles in the at least one channel would be more efficiently disturbed by the piezoelectric units to further escape to a gas-phase space. Hence, the bubbles in a large amount can be prevented from being attached to the surface or the proximity of the boiler plate (or even randomly flowing to the other locations). Therefore, the heats of the boiler plate can be more efficiently removed. Furthermore, through improving the conditions of the bubbles (such as staying in place or flowing to other locations), pollutants generated at the surface or the proximity of the boiler plate can be removed at the same time. Therefore, the pollutants that would further affect the cooling performance of the boiler plate can be prevented from being accumulated at the surface or the proximity of the boiler plate. Hence, in some embodiments, the immersion cooling system can prevent from apparently affecting the original heat transfer rate of the heat transfer fluid and the original working performance of the boiler plate (as well as the attached elements of the boiler plate). Therefore, in some embodiments, the boiler plate and the attached elements of the boiler plate can reach superior working performances and service lives.

Although the present disclosure is disclosed in the foregoing embodiments as above, it is not intended to limit the instant disclosure. Any person who is familiar with the relevant art can make some changes and modifications without departing from the spirit and scope of the present disclosure. Therefore, the scope of the present disclosure shall be subject to the definition of the scope of patent application attached to the specification.

What is claimed is:

1. An immersion cooling system comprising:
a cooling tank having a receiving portion;
an immersion unit in the receiving portion and comprising a boiler plate;
a plurality of piezoelectric units, wherein at least one channel is between the piezoelectric units, and the at least one channel is in communication with the boiler plate; and
a piezoelectric driver for driving each of the piezoelectric units to generate a deformation.

2. The immersion cooling system according to claim 1, wherein the deformation of each of the piezoelectric units has a deformation direction, and the deformation directions of each two adjacent of the piezoelectric units are in opposite directions.

3. The immersion cooling system according to claim 1, wherein the piezoelectric units have a plurality of the channels gradually expanding along a direction away from the boiler plate.

4. The immersion cooling system according to claim 1, wherein the piezoelectric units have a plurality of the channels gradually tapered along a direction away from the boiler plate.

5. The immersion cooling system according to claim 1, wherein the piezoelectric units have a plurality of the channels gradually expanding upwards along a vertical direction.

6. The immersion cooling system according to claim 1, wherein the piezoelectric units have an overall width, and the overall width is greater than or equal to a plate width of the boiler plate.

7. The immersion cooling system according to claim 1, wherein the piezoelectric units respectively have vertical heights substantially equal to each other, and the vertical heights of the piezoelectric units are not lower than a vertical height of the boiler plate.

8. The immersion cooling system according to claim 1, wherein the deformation of each of the piezoelectric units has a deformation extent, the piezoelectric units comprise a plurality of side piezoelectric units at two sides of the piezoelectric units and at least one middle piezoelectric unit at the middle of the piezoelectric units, wherein the deformation extent of the at least one middle piezoelectric unit is greater than the deformation extents of the side piezoelectric units.

9. The immersion cooling system according to claim 1, wherein each of the piezoelectric units comprises a piezoelectric frame and an acting section, the action section is at a location of the piezoelectric frame, and the location is adjacent to the boiler plate.

10. The immersion cooling system according to claim 1, wherein each of the piezoelectric units comprises a piezoelectric frame and two acting sections in pair, the two acting sections in pair are respectively at two opposite sides of the piezoelectric frame and correspond to each other, the two acting sections in pair are respectively at locations of the piezoelectric frame, and the locations are adjacent to the boiler plate.

11. The immersion cooling system according to claim 1, further comprising a heat transfer fluid, wherein the heat transfer fluid is received in the receiving portion and at least submerges the boiler plate of each of the immersion units; and each of the immersion unit further comprises:
a main body frame; and
an electronic device in the main body frame, wherein the electronic device comprises a heating element contacting the boiler plate.

12. The immersion cooling system according to claim 11, further comprising a condensation device above a surface of the heat transfer fluid.

13. The immersion cooling system according to claim 11, further comprising a disturbing element comprising a rotation-disturbing element, a rotation-disturbing driver, a jetting element, and a jetting driver, wherein each of the rotation-disturbing element and the jetting element is adjacent to the piezoelectric units, the rotation-disturbing element is driven by the rotation-disturbing driver to generate a disturbance to a direction toward the piezoelectric units, and the jetting element is driven by the jetting driver to generate another disturbance to a direction toward the piezoelectric units.

14. The immersion cooling system according to claim 13, wherein the rotation-disturbing element and the jetting element are adjacent to each other.

15. The immersion cooling system according to claim 13, wherein the rotation-disturbing element and the jetting element are respectively at two opposite sides of the piezoelectric units.

16. The immersion cooling system according to claim 1, further comprising a heat transfer fluid, wherein the heat transfer fluid is received in the receiving portion and at least submerges the boiler plate, wherein the boiler plate faces a surface of the heat transfer fluid.

17. The immersion cooling system according to claim 1, further comprising a heat transfer fluid, wherein the heat transfer fluid is received in the receiving portion and at least submerges the boiler plate, wherein the boiler plate has a main surface substantially parallel to a vertical line.

18. The immersion cooling system according to claim 1, wherein the immersion unit further comprises a bracket in the receiving portion, and the boiler plate is in the bracket.

19. The immersion cooling system according to claim 1, further comprising a plurality of the cooling tanks, a plurality of the immersion units, and a plurality of the piezoelectric drivers, wherein each of the cooling tanks corresponds to a corresponding one of the immersion units, and each of the immersion units corresponds to corresponding piezoelectric units and a corresponding one of the piezoelectric drivers.

20. An immersion cooling system comprising:
a cooling tank having a receiving portion;
an immersion unit in the receiving portion and comprising a boiler plate;
a plurality of piezoelectric units, wherein at least one channel is between the piezoelectric units, and the at least one channel is in communication with the boiler plate;
a piezoelectric driver for driving each of the piezoelectric units to generate a deformation; and
a disturbing unit adjacent to the piezoelectric units and comprising:
a rotation-disturbing element; and
a rotation-disturbing driver, wherein the rotation-disturbing element is driven by the rotation-disturbing driver to generate a disturbance to a direction toward the piezoelectric units.

21. An immersion cooling system comprising:
a cooling tank having a receiving portion;
an immersion unit in the receiving portion and comprising a boiler plate;
a plurality of piezoelectric units, wherein at least one channel is between the piezoelectric units, and the at least one channel is in communication with the boiler plate;
a piezoelectric driver for driving each of the piezoelectric units to generate a deformation; and
a disturbing unit adjacent to the piezoelectric units and comprising:
a jetting element; and
a jetting driver, wherein the jetting element is driven by the jetting driver to generate a disturbance to a direction toward the piezoelectric units.

22. The immersion cooling system according to claim 21, further comprising a heat transfer fluid and a pump device, wherein the heat transfer fluid is received in the receiving portion and at least submerges the boiler plate, the pump device has a first pipeline and a second pipeline, one end of two ends of the first pipeline is under a surface of the heat transfer fluid, and the second pipeline is connected to the jetting element to suction the heat transfer fluid from the first pipeline to accelerate and generate the heat transfer fluid through the second pipeline.
